(19) United States
(12) Patent Application Publication
(10) Pub. No.: US 2023/0009781 A1
(43) Pub. Date: Jan. 12, 2023

(54) SEMICONDUCTOR MOLD LASER CLEANING DEVICE

(71) Applicant: IMT CO., LTD., Gyeonggi-do (KR)

(72) Inventors: Jongmyoung LEE, Gyeonggi-do (KR); Sungho CHO, Gyeonggi-do (KR); Hanseop CHOE, Gyeonggi-do (KR)

(21) Appl. No.: 17/784,567

(22) PCT Filed: Mar. 4, 2020
(86) PCT No.: PCT/KR2020/003067

§ 371 Date: Jun. 10, 2022

(30) Foreign Application Priority Data
Jan. 14, 2020 (KR) 10-2020-0005031

(51) Int. Cl. B08B 7/00; B23K 26/06; B23K 26/082; B29C 33/72

(52) U.S. Cl. CPC B08B 7/0042; B23K 26/0648; B23K 26/0643; B23K 26/082; B29C 33/72

(57) ABSTRACT

A semiconductor mold laser cleaning device of an embodiment includes a laser generator oscillating a pulsed laser beam, an optical fiber transmitting the laser beam, a laser scanning module processing and transmitting the laser beam received through the optical fiber for cleaning the semiconductor mold, the laser scanning module including a laser beam collimator converting the laser beam scattered at one end of the optical fiber into parallel light, a Galvano laser scanner scanning the laser beam, a focal lens focusing the laser beam scanned by the Galvano laser scanner, and a final irradiation mirror redirecting the laser beam passed through the focal lens to deliver the redirected laser beam to the surface of the semiconductor mold, and a conveyance unit conveying the laser scanner module in an X-axis direction and/or a Y-axis direction such that the entire surface of the semiconductor mold can be cleaned.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2020/003067, filed Mar. 4, 2020, which claims priority to the benefit of Korean Patent Application No. 10-2020-0005031 filed in the Korean Intellectual Property Office on Jan. 14, 2020, the entire contents of which are incorporated herein by reference.

### BACKGROUND

### 1. Technical Field

The present invention relates to a device for cleaning foreign matter from a surface of a semiconductor mold using a laser.

### 2. Background Art

In a semiconductor packaging process, a molding process is very important in protection of semiconductor chips and wires. Typically, the molding process is performed by melting a thermosetting composition referred to as an epoxy molding compound (EMC) and molding according to a mold shape, after wire bonding or flip-chip bonding. As the molding process is continued, the surface of the mold is gradually contaminated by EMC residue and a contaminant layer is thickened over time, thereby causing deterioration in brightness on a package mold surface, surface morphology failure, and the like. Accordingly, mold cleaning must be performed to remove EMC residue and the like.

As a typical method for cleaning a semiconductor mold, there is a method of physically removing EMC residue from the semiconductor mold by repeated compression using a melamine resin or rubber that exhibits strong adhesive strength. In general, physical removal of EMC residue through compression is repeatedly performed five times or more and requires a long cleaning time of 1 hour or more. Thus, such a typical cleaning method has problems of significant reduction in operation rate of corresponding equipment due to a long cleaning time, an unpleasant working environment due to the smell of burning rubber, and high consumable costs due to use of expensive cleaning materials.

### SUMMARY

It is an object of the present invention to provide a semiconductor mold laser cleaning device capable of removing residue from a surface of a semiconductor mold at a very high rate using high-speed laser scanning.

In accordance with one aspect of the present invention, there is provided a semiconductor mold laser cleaning device for removing molding resin residues from a surface of a semiconductor mold of semiconductor molding equipment, the laser cleaning device including: a laser generator oscillating a pulsed laser beam; an optical fiber transmitting the laser beam oscillated by the laser generator; a laser scanning module processing and transmitting the laser beam received through the optical fiber to use the laser beam for cleaning the semiconductor mold, the laser scanning module including a laser beam collimator converting the laser beam scattered at an end of the optical fiber into parallel light, a Galvano laser scanner scanning the laser beam at high speed, a focal lens focusing the laser beam scanned by the Galvano laser scanner at a specific focal length, and a final irradiation mirror redirecting the laser beam having passed through the focal lens such that the redirected laser beam is delivered to the surface of the semiconductor mold; and a conveyance unit conveying the laser scanning module at least in an X-axis direction and a Y-axis direction such that the entire surface of the semiconductor mold is cleaned by the laser scanning module. Herein, “surface of the semiconductor mold” is defined as including all surfaces subjected to molding.

According to one embodiment, the laser generator may oscillate a pulsed laser beam having a pulse width or 1,000 nsec or less and a frequency of 1 kHz or more; the laser beam emitted from the laser beam collimator may have a diameter of 5 mm to 10 mm; the Galvano laser scanner may have a linear scanning speed of 10 m/sec or more on a focal surface; the focal lens may have a focal length of 300 mm or more; and the final irradiation mirror may have a length of 50 mm or more.

According to one embodiment, the semiconductor mold may include an upper mold and a lower mold, and the laser scanning module may be placed between the upper mold and the lower mold upon cleaning of the upper mold or the lower mold.

According to one embodiment, the semiconductor mold laser cleaning device may further include a mirror-rotating motor rotating the final irradiation mirror to change a direction of the laser beam finally emitted through the final irradiation mirror so as to clean the upper mold and the lower mold with the laser beam.

According to one embodiment, the semiconductor mold laser cleaning device may further include a sliding table unit placing the laser scanning module at the middle between the upper mold and the lower mold outside the upper mold and the lower mold, and the sliding table unit may include at least one sliding table sliding with respect to a base table placed outside the upper mold and the lower mold.

According to one embodiment, the semiconductor mold laser cleaning device may further include a Z-axis adjustment unit adjusting a height of the sliding table unit.

According to one embodiment, the conveyance unit may include an X-Y conveyance unit mounted on the laser scanning module. The X-Y conveyance unit includes an X-axis guide rail, an X-axis conveyance-driving unit generating driving force for conveyance of the laser scanning module in an X-axis direction to force the laser scanning module to be conveyed along the X-axis guide rail in the X-axis direction, a Y-axis guide rail, and a Y-axis conveyance-driving unit generating driving force for conveyance of the laser scanning module in the Y-axis direction to force the laser scanning module to be conveyed along the Y-axis guide rail in the Y-axis direction.

According to one embodiment, the conveyance unit may include a robot having a robot arm connected at a distal end thereof to the laser scanning module, and the robot and an equipment body including the laser generator may be mounted on an automated guide vehicle.

According to one embodiment, the semiconductor mold laser cleaning device may further include: a protective window covering an opening, through which the laser beam having passed through the final irradiation mirror is discharged, to prevent contamination of the interior of the laser scanning module; and an air sprayer unit disposed outside the high-speed laser scanning module to form an air curtain around the protective window.

Unlike a method of physically removing EMC residues from a semiconductor mold through repeated compression using a melamine resin or rubber, the semiconductor mold laser cleaning device according to the present invention can perform mold cleaning at a very rapid speed, can achieve significant reduction in consumable costs, and can provide safe and eco-friendly operation conditions for operators in performing cleaning operation. In addition, since the semiconductor mold laser cleaning device according to the present invention performs the cleaning operation using a clean energy source, that is, a laser beam, the semiconductor mold laser cleaning device according to the present invention is an eco-friendly device.

The above and other objects, advantageous effects and advantages of the present invention will become apparent from preferable examples of the present invention described below with reference to the accompanying drawings.

### BRIEF DESCRIPTION OF THE DRAWINGS

FIG. 1 is a plan configuration view of a semiconductor mold laser cleaning device according to one embodiment of the present invention.

FIG. 2 is a side configuration view of the semiconductor mold laser cleaning device including components for effectively cleaning an upper semiconductor mold and a lower semiconductor mold according to the embodiment of the present invention.

FIG. 3 is a side configuration view of the semiconductor mold laser cleaning device using a robot for conveyance of a high-speed laser scanning module according to the embodiment of the present invention.

### DETAILED DESCRIPTION

Hereinafter, exemplary embodiments of the present invention will be described in detail with reference to the accompanying drawings. Here, terms or words used in this specification and claims should be interpreted as having meanings or concepts consistent with the technical spirit of the present invention based on the principle that the inventor can appropriately define the concept of the term in order to describe the invention in the best way. It should be noted that detailed descriptions of known functions and constructions which may unnecessarily obscure the subject matter of the present invention are omitted.

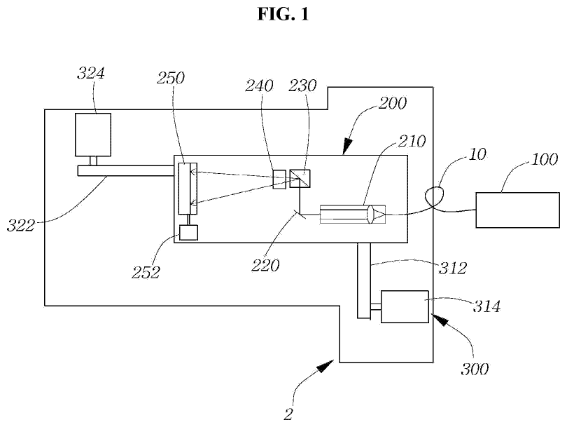

FIG. 1 is a plan configuration view of a semiconductor mold laser cleaning device according to one embodiment of the present invention.

Referring to FIG. 1, the semiconductor mold laser cleaning device according to the embodiment includes: a laser generator 100 oscillating a pulsed laser beam; a high-speed laser scanning module 200 processing and transmitting the laser beam oscillated by the laser generator 100 such that the laser beam can be used in operation of cleaning a semiconductor mold; and an X-Y conveyance unit 300 conveying the high-speed laser scanning module 200 in two dimensions, that is, in an X-axis direction and a Y-axis direction, to adjust an irradiation location of the laser beam delivered from the high-speed laser scanning module 200 to a surface of the semiconductor mold. The high-speed laser scanning module 200 is mounted on the X-Y conveyance unit 300. Here, the X-Y conveyance unit 300 and the high-speed laser scanning module 100 mounted on the X-Y conveyance unit 300 constitute one laser cleaning module 2.

According to this embodiment, the laser generator 100 oscillates the laser beam, which in turn is delivered to the high-speed laser scanning module 200 through an optical fiber 10. The high-speed laser scanning module 200 is adapted to transmit and process the laser beam oscillated by the laser generator 100 such that the laser beam can be used in high speed cleaning of the semiconductor mold (that is, upper and lower molds of semiconductor molding equipment), and includes a laser beam collimator 210, at least one middle reflective mirror 220, a high-speed Galvano laser scanner 230, a focal lens 240, and a final irradiation mirror 250.

The laser beam collimator 210 is connected to one end of the optical fiber 10 and collimates the laser beam scattered at the one end of the optical fiber 10 into parallel light. In addition, the middle reflective mirror 20 serves to reflect the laser beam emitted from the laser beam collimator 210 towards the high-speed Galvano laser scanner 230. Although one middle reflective mirror 20 is used in this embodiment, it should be understood that two or more middle reflective mirrors may be used. The high-speed Galvano laser scanner 230 is configured to perform high speed scanning of the laser beam having passed through at least one middle reflective mirror 20 using a mirror mounted on a scan motor. The laser beam scanned by the high-speed Galvano laser scanner 230 is focused at a specific focal distance through the focal lens 240. Finally, the direction of the laser beam having passed through the focal lens 240 is changed in an upward or downward direction through the final irradiation mirror 250. A mirror-rotating motor 252 is used to change the direction of the laser beam. The mirror-rotating motor 252 changes a traveling direction of the laser beam in the upward or downward direction through automatic change of the direction of the final irradiation mirror 250.

The laser beam subjected to directional change is delivered to a target surface of the semiconductor mold to perform cleaning operation.

The laser generator 100 is configured to oscillate a pulsed laser beam having a pulse width of 1,000 nsec or less and a frequency of 1 kHz or more. Preferably, the laser beam collimated by the laser beam collimator 210 has a diameter of 5 mm to 10 mm. Preferably, the high-speed Galvano laser scanner 230 is configured to have a linear scanning speed of 10 msec or more on a focal plane.

Preferably, the focal lens 240 has a focal length of 300 mm or more and is an f-θ lens, which maintains a focus in a scanning region.

Further, since the length of the final irradiation mirror 250 is very important in securing a sufficient scanning width, the final irradiation mirror 250 preferably has a length of 50 mm or more.

As described above, the laser beam collimator 210, the middle reflective mirror 20, the high-speed Galvano laser scanner 230, the focal lens 240, the final irradiation mirror 250, and the mirror-rotating motor 252 constitute one high-speed laser scanning module 200. The entire surface of the semiconductor mold can be cleaned by conveying the high-speed laser scanning module 200 in the X-axis direction and in the Y-axis direction and the aforementioned X-Y conveyance unit 300 may be used to convey the high-speed laser scanning module 200.

The X-Y conveyance unit 300 includes an X-axis guide rail 312, an X-axis conveyance-driving unit 314 generating driving force for conveyance of the high-speed laser scanning module 200 in the X-axis direction to force the high-speed laser scanning module 200 to be conveyed along the X-axis guide rail 312 in the X-axis direction, a Y-axis guide rail 322, and a Y-axis conveyance-driving unit 324 generating driving force for conveyance of the high-speed laser scanning module 200 in the Y-axis direction to force the high-speed laser scanning module 200 to be conveyed along the Y-axis guide rail 322 in the Y-axis direction. The X-axis conveyance-driving unit 314 may include an X-axis conveyance motor and the Y-axis conveyance-driving unit 324 may include a Y-axis conveyance motor.

The X-Y conveyance unit 300 and the high-speed laser scanning module 200 mounted on the X-Y conveyance unit 300 to be conveyed in the X-axis and Y-axis directions are moved to a space between an upper mold and a lower mold of a semiconductor molding mold to perform overall cleaning operation with respect to an upper surface of the lower mold and a lower surface of the upper mold. In general, the semiconductor molding mold has an EMC port at the center thereof and individual mold cavities at right and left sides thereof. Accordingly, for cleaning of the overall surface of the mold, the high-speed laser scanning module 200 is conveyed in the X-axis direction to be placed at the middle of a half part of the mold and is then conveyed in the Y-axis direction to clean one-side cavity once. Thereafter, the high-speed laser scanning module 200 is conveyed in the X-axis direction to be placed at the middle of the other half part of the mold and is then conveyed in the Y-axis direction to clean the other-side cavity. That is, the half part of the entire mold is processed through Y-axis conveyance of the high-speed laser scanning module 200 once and the other half part of the entire mold is processed through Y-axis conveyance of the high-speed laser scanning module 200 once again after conveyance of the high-speed laser scanning module 200 in the X-axis direction. As a result, the entire surface of the mold can be very rapidly cleaned through conveyance of the high-speed laser scanning module 200 in the Y-axis direction twice. It should be understood that the cleaning operation may be performed several times instead of Y-axis scanning twice for cleaning of the entire surface of the mold. In order to obtain good cleaning quality, a Y-axis scanning speed is important since an overlapping rate of the laser beam is adjusted. Preferably, the Y-axis scanning speed is 1 mm/sec or more. If the scanning speed is too low, there can be a problem of degradation of the mold.

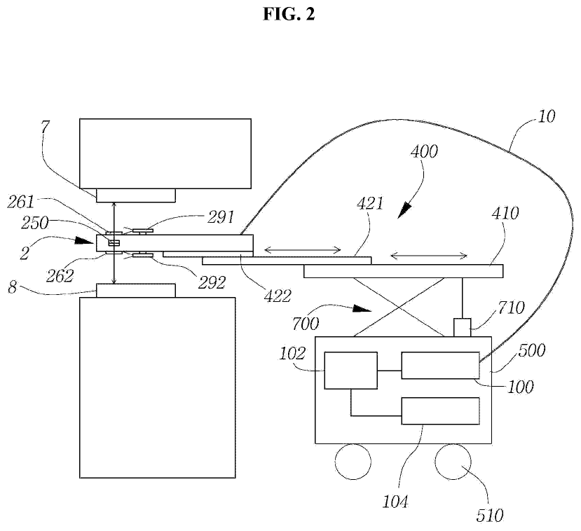

FIG. 2 is a side configuration view of the semiconductor mold laser cleaning device including components for effectively cleaning an upper semiconductor mold and a lower semiconductor mold according to the embodiment of the present invention.

Referring to FIG. 2, the semiconductor mold laser cleaning device according to this embodiment includes a laser cleaner 2, which includes the X-Y conveyance unit 300 (see FIG. 1) and the high-speed laser scanning module 200 (see FIG. 1) mounted on the X-Y conveyance unit 300 (see FIG. 1), and an equipment body 500 provided with wheels 510 and freely movable at a work site, and a sliding table unit 400 disposed above the equipment body 500 to place the laser cleaner 2 at the middle between the upper mold 7 and the lower mold 8 of the semiconductor equipment.

In this embodiment, the sliding table unit 400 includes a base table 410 disposed to allow height adjustment of the sliding table unit 400 with respect to an upper surface of the equipment body 500 in a Z-axis direction and one or more sliding tables 421, 422 disposed to slide away from the base table 410 in the X-axis or Y-axis direction. In this embodiment, the one or more sliding tables 421, 422 include a first sliding table 421 disposed to slide with respect to the base table 410 and a second sliding table 422 disposed to slide with respect to the first sliding table 421. As the number of sliding tables 421, 422, . . . and the number of sliding times increase, it is possible to place the laser cleaner 2 between the upper mold 7 and the lower mold 8, which are separated farther from the equipment body 500. In this embodiment, a final sliding table is the second sliding table 422 on which the laser cleaner 2 including the X-Y conveyance unit 300 (see FIG. 1) and the high-speed laser scanning module 200 (see FIG. 1) mounted on the X-Y conveyance unit is mounted. Accordingly, the high-speed laser scanning module 200 (see FIG. 1) of the laser cleaner 2 can be easily placed between the upper mold 7 and the lower mold 8 using the sliding table unit 400. FIG. 2 schematically shows only a final irradiation mirror 250 and protective windows 261, 262 among several components of the high-speed laser scanning module. The laser beam emitted upwards and downwards through the final irradiation mirror 250 of the high-speed laser scanning module is delivered to the upper mold 7 and the lower mold 8 not shown. Here, a separate optical lens (not shown) may be further disposed between the protective window and the final irradiation mirror.

As described above, when a pushing depth of the laser cleaner 2 in a space between the upper mold 7 and the lower mold 8 is increased, the number of stages of the sliding tables 421, 422 can be increased. A second stage sliding table can place the laser cleaner 2 at a deeper location than a first stage sliding table and a third stage sliding table can place the laser cleaner 2 at a deeper location than the second stage sliding table.

Pieces of the semiconductor molding equipment may have different heights. Accordingly, the height of the laser cleaner 2 including the high-speed laser scanning module is required to be adjusted according to different heights thereof. Height adjustment of the laser cleaner 2 may be achieved by a Z-axis adjustment unit 700 adapted to adjust the height of the sliding table unit 400 connected to the laser cleaner 2 in the Z-axis direction. The Z-axis adjustment unit 700 may employ a motor 710 to achieve automatic height adjustment. Preferably, the height of the laser cleaner 2 is adjusted by driving the motor of the Z-axis adjustment unit 700 corresponding to previously input heights of the pieces of the semiconductor molding equipment.

FIG. 2 shows the protective windows 261, 262 for protection of various optical components together with the final irradiation mirror 250 as parts of a side surface of the high-speed laser scanning module. The protective windows 261, 262 are disposed to cover an opening through which the laser beam having passed through the final irradiation mirror 250 is emitted. The laser beam is emitted outside through the protective windows 261, 262. The protective windows 261, 262 can prevent various optical components inside the high-speed laser scanning module from being contaminated by foreign matter. Further, in order to prevent surfaces of the protective windows 261, 262 from being contaminated by foreign matter in cleaning operation, air sprayer units 291, 292, that is, an upper air sprayer unit 291 and a lower air sprayer unit 292, may be disposed. The air sprayer units 291, 292 form an air curtain around the protective windows 261,262 to prevent contamination of the protective windows 261, 262.

On the other hand, inside the equipment body 500, a controller 102, a power supply 104 and the like may be disposed together with the laser generator 100 according to the above embodiment. As described above, the diameter of the wheels 510 is important for improvement in movability of the equipment body 500. Advantageously, the wheels 510 may have a diameter of 100 mm or more.

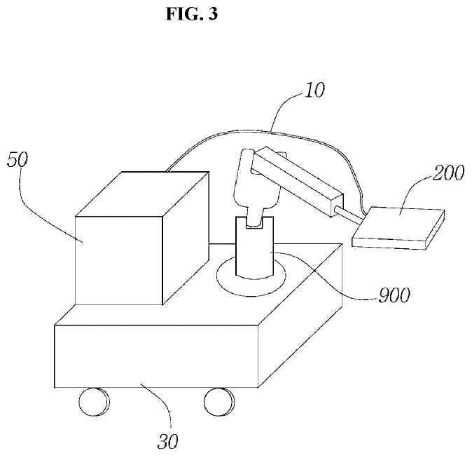

FIG. 3 is a side configuration view of the semiconductor mold laser cleaning device using a robot for conveyance of the high-speed laser scanning module according to the embodiment of the present invention.

In the above embodiments, the high-speed laser scanning module 200 performs cleaning of the entire surface of the mold using the X-Y conveyance unit 300 (see FIG. 1).

FIG. 3 shows cleaning operation, which is performed using a robot 900 instead of the X-Y conveyance unit while moving the high-speed laser scanning module 200 in the X-axis and Y-axis directions. Here, the robot 900 may be a 6-axis articulated robot or a scalar robot. In addition, cleaning equipment 50 including the robot 900 and the laser generator including the high-speed laser scanning module 200 may be mounted on an automated guide vehicle (AGV) 30 to perform cleaning operation while automatically moving to a location of a mold to be cleaned. In recent years, accuracy and reliability of the automated guide vehicle 30 and the robot 900 have been improved to allow the automated guide vehicle 30 and the robot 900 to achieve accurate location of the mold placed at a specific location when information about the location of the mold is input. Accordingly, when the robot 900 and the automated guide vehicle 30 are used, it is advantageously possible to achieve reduction in cost and time required by manual labor through implementation of a fully-automated cleaning operation.

Accordingly, the semiconductor mold laser cleaning device according to the present invention can remove EMC residues from upper and lower surfaces of a semiconductor mold at a very high rate using a laser beam substantially without cost consumption for cleaning and enables very eco-friendly cleaning operation.

It should be understood that the present invention can be applied to any packaging processes for production of semiconductor devices.

Although some embodiments have been described herein, it should be understood by those skilled in the art that these embodiments are given by way of illustration only and the present invention is not limited thereto and that various modifications, variations, and alterations can be made by those skilled in the art without departing from the spirit and scope of the present invention.

1. A semiconductor mold laser cleaning device for removing molding resin residues from a surface of a semiconductor mold of semiconductor molding equipment, the semiconductor mold laser cleaning device comprising:
a laser generator configured to oscillate a pulsed laser beam;
an optical fiber configured to transmit the laser beam oscillated by the laser generator;
a laser scanning module configured to process and transmit the laser beam received through the optical fiber to use the laser beam for cleaning the semiconductor mold, the laser scanning module comprising a laser beam collimator configured to convert the laser beam scattered at one end of the optical fiber into parallel light, a Galvano laser scanner configured to scan the laser beam at high speed, a focal lens configured to focus the laser beam scanned by the Galvano laser scanner at a specific focal length, and a final irradiation mirror configured to redirect the laser beam having passed through the focal lens such that the redirected laser beam is delivered to the surface of the semiconductor mold; and
a conveyance unit configured to convey the laser scanning module at least in an X-axis direction and a Y-axis direction such that an entire surface of the semiconductor mold can be cleaned by the laser scanning module.

2. The semiconductor mold laser cleaning device according to claim 1, wherein the laser generator oscillates a pulsed laser beam having a pulse width or 1,000 nsec or less and a frequency of 1 kHz or more; the laser beam emitted from the laser beam collimator has a diameter of 5 mm to 10 mm;
the Galvano laser scanner has a linear scanning speed of 10 m/sec or more on a focal surface;
the focal lens has a focal length of 300 mm or more; and
the final irradiation mirror has a length of 50 mm or more.

3. The semiconductor mold laser cleaning device according to claim 1, wherein the semiconductor mold comprises an upper mold and a lower mold, and the laser scanning module is placed between the upper mold and the lower mold upon cleaning of the upper mold or the lower mold.

4. The semiconductor mold laser cleaning device according to claim 3, further comprising:
a mirror-rotating motor configured to rotate the final irradiation mirror to change a direction of the laser beam finally emitted through the final irradiation mirror so as to clean the upper mold and the lower mold with the laser beam.

5. The semiconductor mold laser cleaning device according to claim 3, further comprising:
a sliding table unit configured to place the laser scanning module at the middle between the upper mold and the lower mold outside the upper mold and the lower mold, the sliding table unit comprising at least one sliding table sliding with respect to a base table placed outside the upper mold and the lower mold.

6. The semiconductor mold laser cleaning device according to claim 5, further comprising:
a Z-axis adjustment unit configured to adjust a height of the sliding table unit.

7. The semiconductor mold laser cleaning device according to claim 1, wherein the conveyance unit comprises an X-Y conveyance unit mounted on the laser scanning module, and the X-Y conveyance unit comprises:
an X-axis guide rail;
an X-axis conveyance-driving unit configured to generate driving force for conveyance of the laser scanning module in an X-axis direction to force the laser scanning module to be conveyed along the X-axis guide rail in the X-axis directions;
a Y-axis guide rail; and
a Y-axis conveyance-driving unit configured to generate driving force for conveyance of the laser scanning module in the Y-axis direction to force the laser scanning module to be conveyed along the Y-axis guide rail in the Y-axis direction.

8. The semiconductor mold laser cleaning device according to claim 1, wherein the conveyance unit comprises a robot having a robot arm connected at a distal end thereof to the laser scanning module, and the robot and an equipment body comprising the laser generator are mounted on an automated guide vehicle.

9. The semiconductor mold laser cleaning device according to claim 1, further comprising:
a protective window covering an opening, through which the laser beam having passed through the final irradiation mirror is discharged, to prevent contamination of an interior of the laser scanning module; and
an air sprayer unit disposed outside the high-speed laser scanning module to form an air curtain around the protective window.
